(19) United States
(12) Patent Application Publication
(10) Pub. No.: US 2008/0149159 A1
(43) Pub. Date: Jun. 26, 2008

(54) Thermoenergy devices and methods for manufacturing same

(76) Inventors: Mark Logan, Pleasant Valley, NY (US); Frederick A. Flitsch, New Windsor, NY (US); Lloyd Wright, Hopewell Junction, NY (US); Lloyd Young, Pleasant Valley, NY (US)

Correspondence Address: Joseph P. Kincart, Esq., 8153 Middle Fork Way, Jacksonville, FL, 32256, US

(21) Appl. No.: 11/642,362

(22) Filed: Dec. 20, 2006

(51) Int. Cl. H01L 35/30

(52) U.S. Cl. 136/205

(57) ABSTRACT

The present invention provides thermoelectric or thermodiodic devices and methods for manufacturing such devices.

### CROSS REFERENCE TO RELATED APPLICATIONS

This application claims priority to the Provisional Application Ser. No. 60/751,673, filed Dec. 19, 2005 and entitled: “Thermoenergy Devices and Methods for Manufacturing Same.” The contents of each are relied upon and incorporated herein by reference.

### FIELD OF THE INVENTION

This invention relates generally to devices with thermoelectric and thermal diodic characteristics. In particular the present invention combines thermoelectric devices with thermal diodes to provide efficient thermal energy transfer devices that may be useful for power generation applications and cooling/heating applications.

### SUMMARY

Thermocouples operating in accordance with the Peltier effect are well known in the arts. Applications for thermoelectric devices include heating, power generation and temperature sensing. However, the efficiency of previously known thermoelectric devices limited their usefulness.

According to Peltier, arranging two dissimilar conductors next to each other and applying a voltage differential across the conductors can create a thermo electric device. Thermoelectric devices, including, for example, Peltier Crystals, may be formed, for example, with two dissimilar semiconductors, such as bismuth telluride (Bi₂Te₃) doped with selenium and antimony (Bi,Sb)₂Te₃ & Bi₂(Te,Se)₃ to form N-type and P-type materials. Other exemplary materials may include PbTe and SiGe.

With a voltage applied across the two types of materials, the electrons in each material have a different potential energy. Therefore to move from one type of material to another type of material, the electrons must either absorb energy or release it, depending upon which direction they travel. Therefore, with a thermoelectric device the application of a voltage can cause thermal energy to be absorbed on one side of the device and released on the other.

The efficiency of a Peltier Crystal thermoelectric device is generally limited to an associated Carnot cycle efficiency reduced by a factor which is dependent upon the thermoelectric figure of merit of materials used in fabrication of the associated thermoelectric elements, ZT, where Z=α²/ρλ with α=the Seebeck coefficient (the change in voltage with temperature dV/dT), ρ=the electrical resistivity, and λ=the thermal conductivity. As can be seen from the definition of Z, the efficiency of a thermoelectric device decreases with increasing thermal conductivity or electrical resistivity. Improving the efficiency of thermoelectric devices requires either increasing the Seebeck coefficient or reducing the thermal conductivity or electrical resistivity. According to the present invention, the thermal conductivity is reduced with a thermal diode.

Additionally, in some embodiments, a composite device can include a first portion with more conventional Peltier material and a second portion with TTD material and lower thermal conductivity to form it is also true of the present invention that the temperature gradient across the conventional device is kept as close to 0 as possible; equally reducing the effect of thermal conductivity.

According to some embodiments, a Peltier Crystal can be fashioned by extruding a billet of P-type material to form a P-type extrusion, also extruding a billet of N-type material to form an N-type extrusion. The P and N-type extrusions can be sliced into wafers; the wafers can be sliced into small elements. The elements can be mechanically loaded, for example, into a matrix of a desired pattern and assembled upon an electrically insulating plate with small copper pads connecting elements electrically in series and thermally in parallel on the plate.

Other embodiments can include forming a thermoelectric material by combining a P-type extrusion with a N-type extrusion to form a P/N-type billet. The P/N-type billet may be extruded to form a P/N-type extrusion having P-type regions, and N-type regions. According to these embodiments, the number of P-type regions and N-type regions can correspond with the number of P-type extrusions and N-type extrusions used to form the P/N-type billet.

Some embodiments can also include a thermoelectric module with two ceramic substrate plates that serve as a foundation and also as electrical insulation for P-type and N-type Bismuth Telluride blocks. A pattern of blocks can be laid out on the ceramic substrates so that they are electrically connected in series configuration. The position of the blocks between the two ceramic substrates can provide a parallel configuration for the thermal characteristics of the blocks. The ceramic plates can also serve as insulation between a) the blocks internal electrical elements and a thermal energy sink that will typically be placed in contact with the hot side and b) the blocks internal electrical elements and whatever may be in contact with the cold side area.

Embodiments can include modules with an even number of P-type and N-type blocks. The blocks are arranged, for example, so that one of each type of block shares an electrical interconnection often referred to as a “couple.”

As discussed above, it is known for P-type to be fashioned from an alloy of Bismuth and the N-type to be fashioned from an alloy of Tellurium. Both Bismuth and Tellurium have different free electron densities at the same temperature. P-type blocks are composed of material having a deficiency of electrons while N-type has an excess of electrons. As current flows through the module (up and down through the blocks) the amperage attempts to establish equilibrium throughout the module. The current causes the P-type material to become analogous to a hot area that will be cooled and the N-type to become analogous to a cool area that will be heated. Since both materials are actually at the same temperature, the result of the applied current is that the hot side of the module is heated and the cold side of the module is cooled. Since direct current is applied, the direction of the current can be used to determine whether a particular side of the module will be cooled or heated. Simple reversal of the DC polarity will switch the hot and cold sides.

Various features and embodiments are further described in the following figures, drawings and claims.

### DESCRIPTION OF THE DRAWINGS

FIG. 1 illustrates a block diagram of some embodiments of the present invention comprising a combination of a thermoelectric device and a thermal diode.

FIG. 2 illustrates a block diagram of some embodiments of the present invention comprising a layered combination including a thermal diode bordered by a thermoelectric device on two areas.

FIG. 3 illustrates a block diagram of some embodiments of the present invention comprising a layered combination including multiple thermal diodes bordered and thermoelectric devices.

FIG. 4 illustrates an exemplary basic thermal device implementing aspects of the present invention.

FIG. 5 illustrates some exemplary embodiments of the present invention comprising Peltier crystals.

FIG. 6 illustrates some exemplary embodiments of the present invention comprising micro sized units with an ionic conductive layer.

FIG. 7 illustrates some exemplary embodiments of the present invention comprising Peltier crystals.

FIG. 8 illustrates some exemplary embodiments of the present invention comprising thermal diode portions and thermoelectric portions with varying surface areas.

FIG. 9 illustrates some exemplary embodiments of thermoelectric device portions.

FIG. 10 illustrates some exemplary embodiments of the present invention comprising at least one thermoelectric device portion, at least one thermal diode portion and at least one thermal energy sink portion.

### DETAILED DESCRIPTION

Overview

The present invention provides devices which combine thermoelectric devices with thermal diodes thereby providing an efficient means of transferring thermal energy from a first area to a second area. As referred to herein, a thermoelectric device includes any device that can respond to the application of a DC voltage by transferring thermal energy from a first portion to a second portion, a Peltier Crystal includes a thermoelectric device with dissimilar materials that is capable of controllably transferring thermal energy from one portion of the device to another portion of the device or alternatively, creating a voltage when a temperature differential is applied across the dissimilar portions. A thermal diode includes a diodic device capable of controllably transferring thermal energy in one direction from one portion of the diodic device to another portion of the diodic device and to resist the transfer of thermal energy in the opposing direction.

As presented herein, various embodiments of the present invention will be described followed by some specific examples of various components of the devices presented herein and examples of how the various components may be combined.

### Thermal Energy Devices

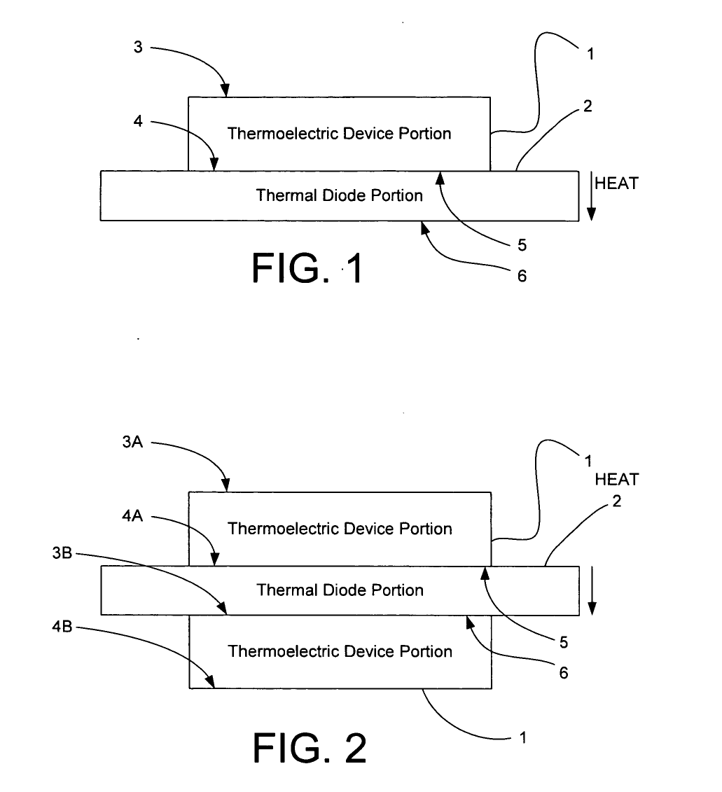

Referring now to FIG. 1, a block diagram of a device according to some embodiments of the present invention illustrates a device with a thermoelectric device portion 1 and a thermodiodic portion 2.

According to the present invention, the thermoelectric device portion 1 which is capable of conducting thermal energy from a first area 3, to a second area 4 with the application of a direct current (DC) voltage across the thermoelectric device 1, is fashioned adjacent to a thermal diode portion 2. Inherent in the thermoelectric device 1 can be a tendency to have thermal conductivity transfer thermal energy back across the device from the second area 4 to the first area 3. However, with the application of a DC voltage across the thermal diode 2, the thermal diode 2 will conduct thermal energy away from a first area of the thermal diode 5 to a second area of the thermal diode 6 with little or no thermal conductivity from the second area of the thermal diode 6 back to the first area of the thermal diode 5.

Embodiments of the present invention are therefore capable of transferring thermal energy away from the second area of the thermoelectric device 4. With thermal energy being transferred away from the second area of the thermoelectric device 4, the temperature differential between the first area of the thermoelectric device 3 and the second area of the thermoelectric device 4 is decreased resulting in less thermal energy being conducted back across the thermoelectric device from the second area 4 to the first area 3.

Devices according to the present invention therefore provide more efficient thermal energy transfer from a first side of the device 3 to a second side of the device 6.

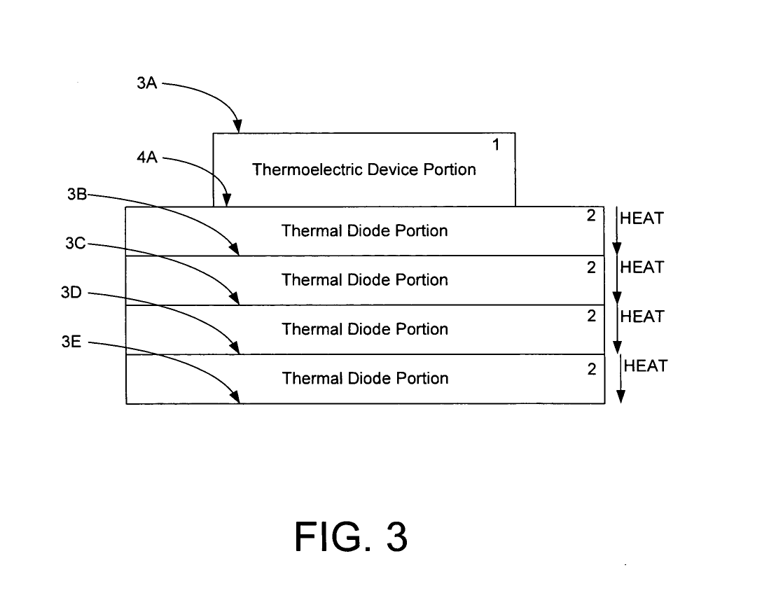

Referring now to FIG. 2, in some embodiments of the present invention, one or more layers of thermoelectric devices 1 and thermal diodes 2 can be combined to increase the power generation capacity or increase the efficiency to transfer thermal energy, according to a particular application. Multiple layers of thermal diodes 2 can be arranged in thermal and electrical series, for example as illustrated in FIG. 3, and control the temperature differential across any particular thermal diode portion 2. Control of the temperature differential can be useful, for example, to limit any adverse physical effects, such as expansion or contraction that may cause cracking between layers that would otherwise have larger temperature differential.

The thermal energy differential of a particular thermal diode portion 2, can be controlled by controlling a voltage applied across the particular diode 2, when individual diode control is afforded, or by the aggregate voltage across the entire stack of thermal diodes in an application for transferring thermal energy.

### Thermal Diodic Portions

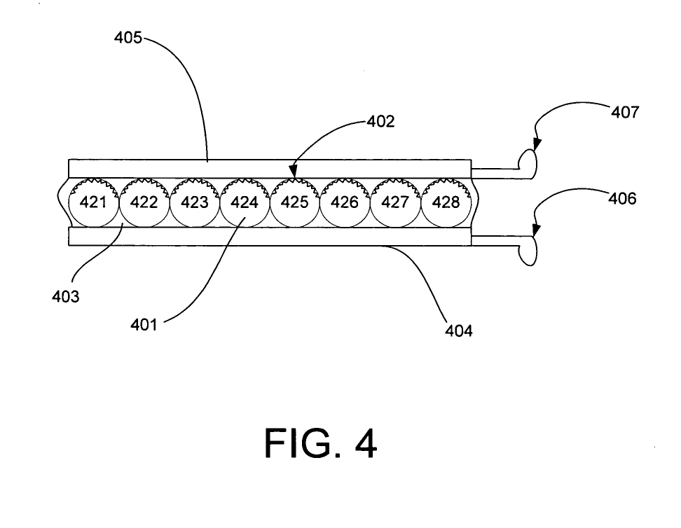

Referring now to FIG. 4, the thermal diode portion 2 incorporated into the present invention can include any thermal diode design capable of being fashioned to a thermoelectric device 2 For example, embodiments of the present invention include a textured thermodiodic device (TTD) that includes a first substrate layer 404 with a first conductive layer 401 with micro sized units 421-428 and an insulator 403 between at least some of the micro sized units 421-428. The micro sized units 401 are in electrical contact with the first substrate layer 404. The micro sized units 421-428 can also be in electrical contact with a layer of ionic conductor 402, which in turn is in contact with a second conductive substrate 405. The first conductive substrate 404 and the second conductive substrate 405 can each have a respective connector portion 406 and 407.

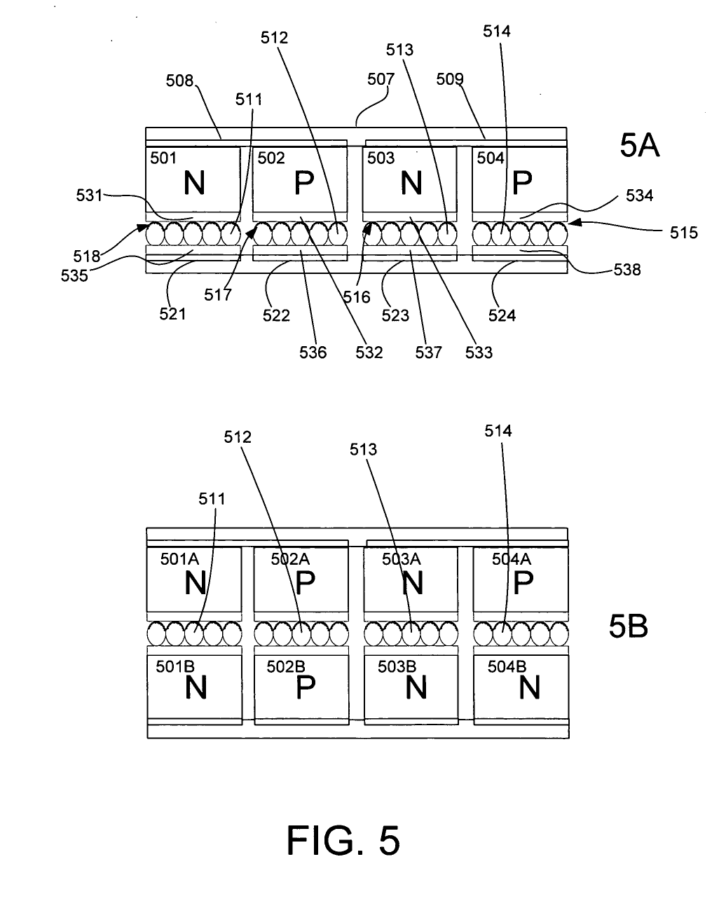

Referring now to FIG. 5, according to some embodiments of the present invention, Peltier crystal arrays including elements of N-type material 501,503 and elements of P-type material 502, 504 are combined with a individual layers of micro sized units 511-514 which can each be formed with a layer of ionic conductor 515-518. The layers of micro sized units 511-514 can each be made up of essentially a monolayer of multiple conductive material units, such as, for example, units of Ag or any other conductive species which can be reacted to form an ionic conductor.

At 5A, the layers of micro sized units 511-514 each with an ionic conductor layer 515-518 can be arranged between the Peltier crystals of N-type elements 501, 503 and P-type elements 502,504, and conductive plates 521-524 arranged on an electrically insulating substrate block 510. The N-type blocks 501, 503 and P-type blocks 502, 504 can be electrically connected in series and thermally connected in parallel with the conductive plates. In some embodiments, conductive substrate layers 531-538 can be included on either side of the layers of micro sized units 511-514 with the ionic conductor layers 515-518.

Various embodiments can also include additional layers according to desired characteristics of a device, such as, for example a thermal diode characteristic. For example, at 5B, the layers of micro sized units 511-514 with the ionic conductor layers 515-518 can be sandwiched in between the Peltier crystals of N-type elements 501A, 501B and 503A, 503B and P-type elements 502A, 502B and 504A, 504B.

The one or more layers of micro sized units 511-514 with the ionic conductor layers 515-518 fashioned in series with the N-type and P-type elements can act as a thermal diode and block the thermal conduction from a hot side to a cold side of a module that includes both the N-type and P-type elements and the one or more layers of micro sized units 511-514 with the ionic conductor layers 515-518. In this arrangement, the current that flows through the N-type and P-type elements will also flow through the one or more layers of micro sized units 511-514 with the ionic conductor layers 515-518 and cause the one or more layers of micro sized units 511-514 with the ionic conductor layers 515-518 to also act as a heat pump. The ionic conductor layers 515-518 will also act to prevent thermal conduction of thermal energy back through the one or more layers of micro sized units 511-514 with the ionic conductor layers 515-518, essentially creating a thermal diode.

### Peltier Crystals

To form the elements of N-type material 501, 503 and elements of P-type material 502, 504, billets of N-type material can be extruded to form an N-type extrusion and billets of P-type material can be extruded to form a P-type extrusion. The N and P-type extrusions can each sliced into wafers, the wafers are sliced into small elements, and the elements are mechanically loaded into a matrix of a desired pattern and assembled upon an electrically insulating plate 507 with small copper pads 509-510 connecting the N-type elements and the P-type elements electrically in series and thermally in parallel on the plate 507.

In other embodiments, a N-type extrusion and a P-type extrusion can be combined to form a N/P-type billet. The N/P-type billet (not shown) may be extruded to form a N/P-type extrusion having N-type regions, and P-type regions. According to these embodiments, the number of N-type regions and P-type regions can correspond with the number of N-type extrusions 501, 503 and P-type extrusions 502,504 used to form the N/P-type billet.

In some embodiments that include N-type and P-type elements and at least one layer of micro sized units with an ionic conductor layer, the P-type material can be fashioned from an alloy of Bismuth and the N-type can be fashioned from an alloy of Tellurium. Both Bismuth and Tellurium have different free electron densities at the same temperature. P-type blocks can include a material having a deficiency of electrons while N-type can have an excess of electrons.

As current flows through a module of N-type and P-type elements (up and down through the elements) the amperage attempts to establish equilibrium throughout the N-type and P-type elements. The current causes the P-type material to become analogous to a hot area that will be cooled and the N-type to become analogous to a cool area that will be heated. Since both materials are actually at the same temperature, the result of the applied current is that the hot side of the module is heated and the cold side of the module is cooled. Application of direct current (DC) can be used to determine whether a particular side of the module will be cooled or heated. Reversal of the DC polarity can be used to switch the hot and cold sides.

Some embodiments can include a Peltier Crystal that includes a tunneling-effect converter of thermal energy to electricity with an emitter and a collector separated from each other by a distance that is comparable to atomic dimensions and where tunneling effect plays an important role in the charge movement from the emitter to the collector across the gap separating such emitter and collector. At least one of the emitter and collector structures includes a flexible structure. Tunneling-effect converters include devices that convert thermal energy to electrical energy and devices that provide refrigeration when electric power is supplied to such devices.

Still other embodiments can include one or more Peltier Crystal portions with a tunneling-effect converter, that includes: an electric charge collector having a collector surface, wherein said collector surface is atomically smooth; an electric charge emitter having an emitter surface, wherein said emitter surface is atomically smooth and wherein said emitter surface is separated from said collector surface by a gap such that said emitter surface is separated from said collector surface by a distance that is less than or equal to about 5 nm; and a spacer between said collector and said emitter, wherein said spacer includes dielectric material in contact with said collector surface and with said emitter surface.

Some embodiments can also include one or more Peltier Crystal portions with a tunneling-effect converter that includes: an electric charge collector having a collector surface; an electric charge emitter having an emitter surface, wherein the collector surface is separated from said emitter surface by a distance such that the probability for electron tunneling between said emitter surface and the collector surface is at least 0.1%; and a spacer between said collector and the emitter, wherein said spacer can include a dielectric material in contact with said collector surface and with said emitter surface.

Still other embodiments can include one or more Peltier Crystal portions with a tunneling-effect converter, that includes: an electric charge collector having a collector surface; an electric charge emitter having an emitter surface, wherein at least one of the collector and the emitter comprises an electrically conductive flexible layer; and a spacer between said collector and the emitter, wherein the spacer comprises dielectric material in contact with the collector surface and the emitter surface, and wherein the emitter surface is separated from the collector surface by a distance that is less than or equal to 5 nm.

Some embodiments can also include one or more Peltier Crystal portions with a tunneling-effect converter that includes: an electric charge collector having a collector surface that is atomically smooth; an electric charge emitter having an emitter surface that is atomically smooth, wherein at least one of said collector and the emitter is a flexible electrode; a spacer between the collector and said emitter, wherein the spacer includes dielectric material in contact with the collector surface and the emitter surface; and a means for load distribution applied to said flexible electrode.

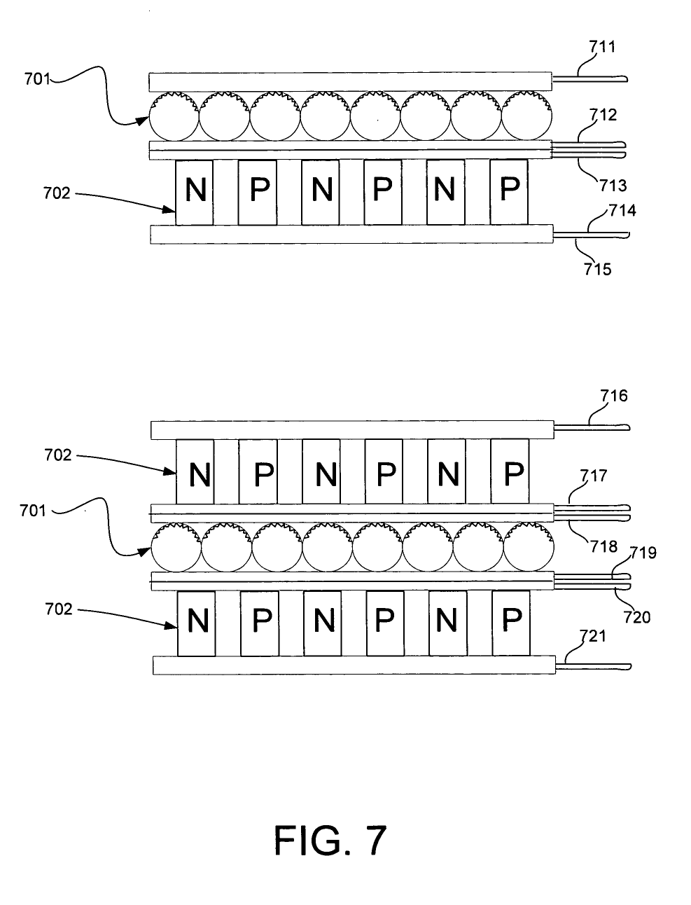

Referring now to FIG. 7, those schooled in the arts will also understand that some basic embodiments of the present invention micro sized units, can include sphere shaped units, having nano sized ionic conductor layers which can also be incorporated into multiple devices having various applications. Therefore, for example, some basic embodiments can include a first conductive layer with micro sized units, such as sphere shaped units, such as silver, and the sphere shaped silver units having a nano sized conductive ionic conductor layer, such as silver sulfide, in between the first conductive layer and the second conductive layer. Embodiments can also include, for example, a first conductor layer that includes units of between 0.800 microns and 2 microns and the ionic conductor layer is between 80 and 120 angstroms. Other embodiments can include a first conductor layer that includes a non-metallic material, such as, for example, latex, coated with a conductive coating, such as, for example, silver.

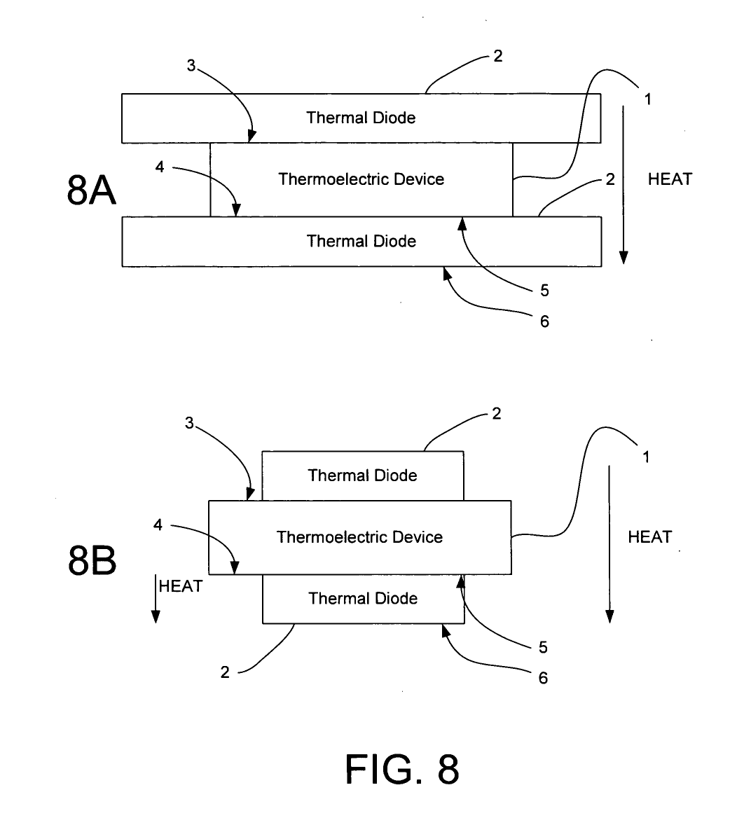

The separate leads in FIG. 7 shown as items 711-721 are exemplary of the fact that the individual stacked components can be made to be individually connected to electrical power supplies and therefore adjusted for consistency between the diodic layer(s) and the thermoelectric layer(s). It should be obvious that by connecting any adjacent pairs of the electrical leads, for example 712, 713 that the composite device can be made to conduct the electrical current in a series manner. In such a connection, it is possible that the series current would yield different cooling rates for the two device types which could be an inconsistent mode of operation. FIG. 8 demonstrates the concept that could be applied to scale the device area in those composite devices where the current is driven in series through all components of the composite device.

Referring now to FIG. 8, some embodiments are illustrated which demonstrate that one or more thermal diode portions can be matched with a thermoelectric portion with different surface area characteristics. For example, in FIG. 8A, two thermal diode portions 2 are situated on either side of a thermoelectric portion 1 and each of the thermal diode portions 2 have a greater surface area than the thermoelectric portion 1. In FIG. 8B, two thermal diode portions 2 are situated on either side of a thermoelectric portion 1 and each of the thermal diode portions 2 has a surface area less than the surface area of the thermoelectric portion 1. Some embodiments can include thermal diode portions and thermoelectric portions which have relative sizes such that when a given current is applied across the portions in aggregate, thermal energy is transferred across each of the portions at relative rate and in a predetermined direction.

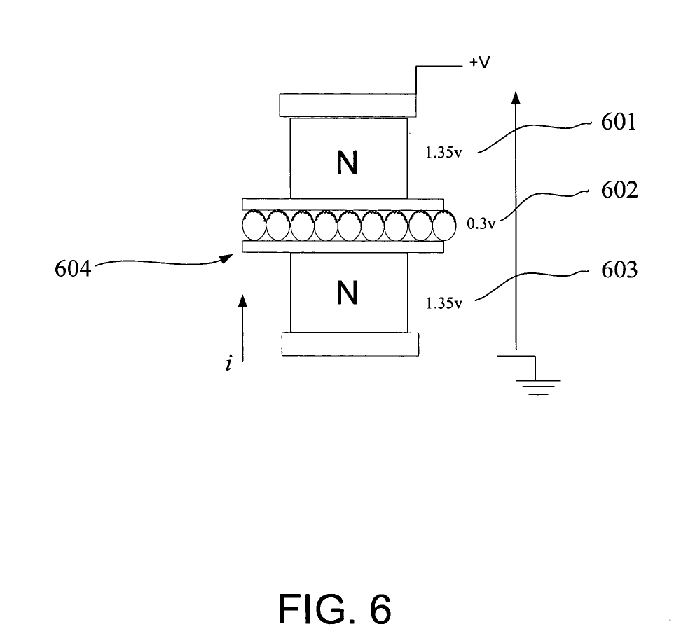

Referring now to FIG. 6, a Peltier crystal with N-type material is illustrated with a layer of micro sized units and an ionic conductor layer. A series current flow is shown through the N-type material and the layer of micro sized units and the ionic conductor layer. Exemplary voltage drops are also shown to illustrate how a particular voltage drop can be engineered by adjusting the surface area through which the current i will pass. The example illustrated shows a 3.0v differential applied across the device with 1.35 v dropping across a first layer of P-type material 601 and a 1.35 v drop across a second layer of P-type material 603. A 0.3v drop 603 is shown across the layer of micro sized units and an ionic conductor layer. Those skilled in the art will understand that the exemplary voltages can also be greater or lesser, including a magnitude higher or lower. Therefore some embodiments may include, for example, a greater differential of about 30v, or a lower differential of about 0.3v applied across the device, or any positive or negative voltage capable of activating the device to transfer thermal energy.

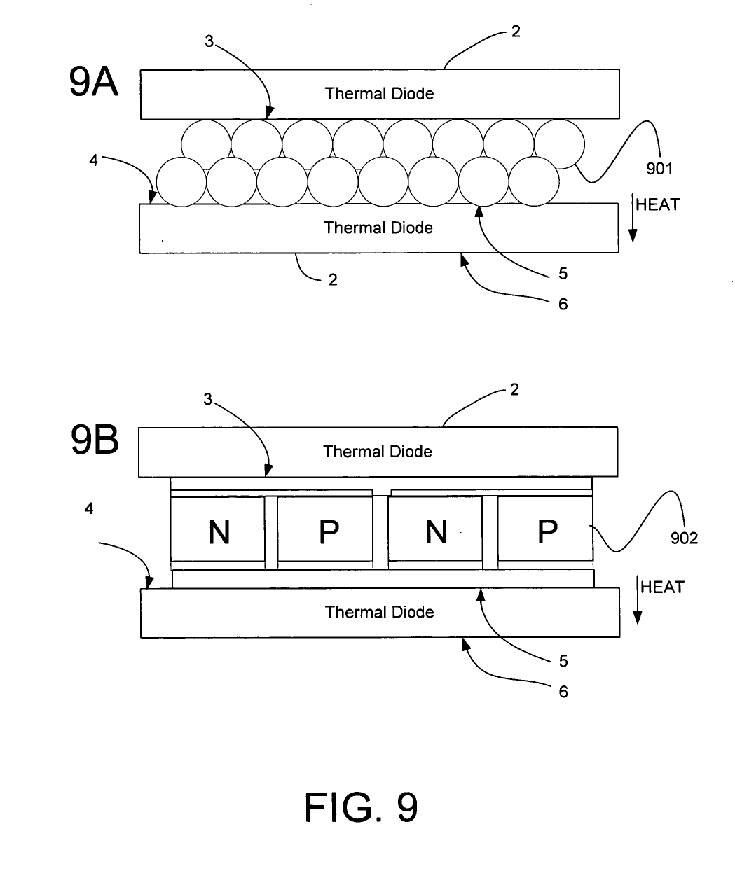

Referring now to FIG. 9, some specific examples of some embodiments can include thermoelectric portions with different structures. For example, FIG. 9A illustrates a thermoelectric portion fashioned with essentially spherical units 901. Some exemplary embodiments can include a thermoelectric portion with a thermally conductive electron emitter and a thermally conductive electron collector and a gap between the thermally conductive electron emitter and thermally conductive collector. In some embodiments, including a thermal diode along one or more surfaces of the thermoelectric portion can greatly increase the efficiency of the thermoelectric device by applying a current across the thermal diode portion to maintain a preferred temperature differential across the thermoelectric portion. It should be noted that in such a composite device where the hot side is defined at 2 at some temperature Tₕ and a cold side 6 at some temperature T_{c}, the actual temperature delta across the thermoelectric device which would be the temperature at 3 versus the temperature 4 could be even greater than Tₕ-T_{c}, by the application of current across the individual diode components to pump heat from the hot side and heat away into the cold side. Application of currents across the individual portions provides the unique ability of transferring thermal energy through the individual portions under conditions which may be different for each respective portion. For example, a current may be applied across each of the thermal diode portions to transfer thermal energy to or from a surface of the thermoelectric portion so that the thermoelectric portion can be made to operate (transfer thermal energy) within preferred conditions. Conditions can include, for example, preferred temperature ranges and preferred temperature differentials across one or more of the thermoelectric portions and the thermal diode portions.

Other embodiments may include a tunneling effect thermoelectric portion with a charge collector and a charge emitter and a spacer of dielectric material which provides a distance between the emitter and the collector. In some specific embodiments, the emitter and collector can include surfaces which are atomically smooth.

At 9B, thermoelectric portion that includes a Peltier type device with N-type material and P-type material is illustrated. The N-type and P-type materials can include, for example two dissimilar semiconductors, such as bismuth telluride (Bi₂Te₃) doped with selenium and antimony (Bi,Sb)₂Te₃ & Bi₂(Te,Se)₃ to form N-type and P-type materials. Other exemplary materials may include PbTe and SiGe.

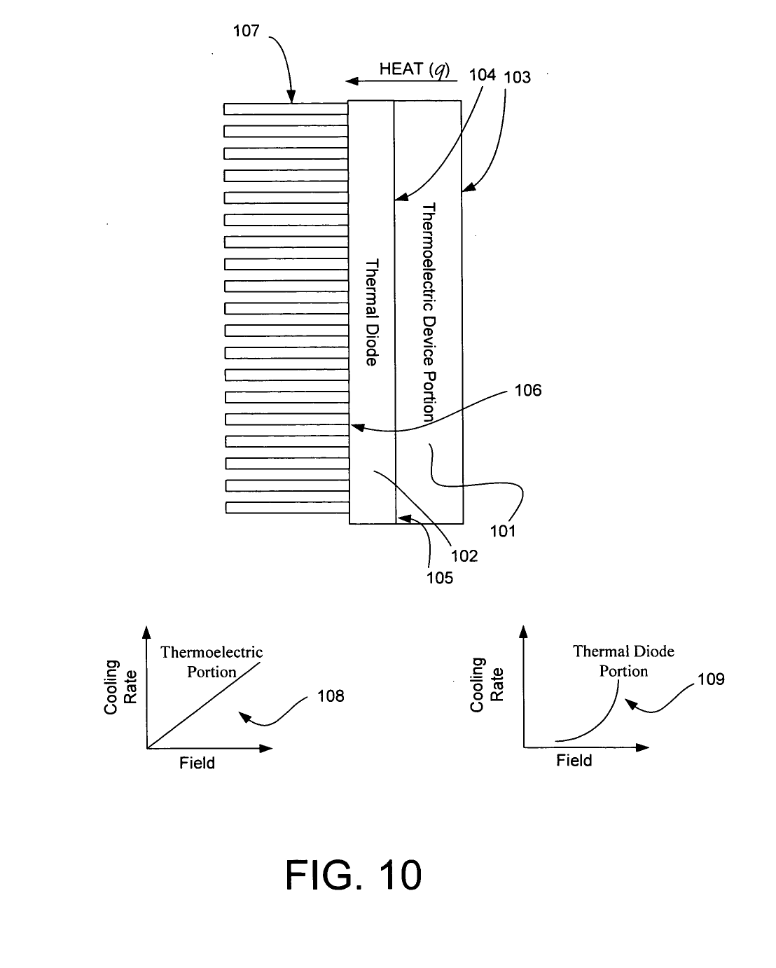

Referring now to FIG. 10, one exemplary application is illustrated showing how a current can be applied across a thermoelectric portion 101 to transfer thermal energy in the form of heat (q) from a first surface 103 to a second surface 104. A current can also be applied across a thermal diode portion 102 to transfer thermal energy from a third surface 105 which is in thermal contact with the surface 104, to a fourth surface 106. In various embodiments, the currents across the thermoelectric portions and the thermal diode portions may be the same current, or individually applied currents. The fourth surface 106 can also be thermal contact with a thermal energy sink 107, such as, for example, fins for cooling by ambient air, or liquid cooling.

In some embodiments, the current applied across the thermoelectric portion 101 and the thermal diode portion 102 can be individually controlled according to the relative ability of each portion to transfer thermal energy and the amount of thermal energy that needs to be transferred. For example, some embodiments may include a thermoelectric portion 101 for which the relationship between the field created by the current applied across the thermoelectric portion 101 and the efficiency of the thermal energy transfer is essentially linear 108. In addition, some embodiments may include a thermal diode portion 102 for which the efficiency of thermal energy transfer may decrease once a threshold current is reached 109.

Some embodiments can therefore include individually adjusting the current across the various portions to obtain a desired result. For example, a current may be applied across the thermal diode portion 102 to create a thermal transfer, however, if the demand for thermal energy transfer increases in a transient fashion to the point where the current that needs to be applied across the thermal diode 102 pushes the thermal diode 102 into a less efficient range, then a current may also be applied across the thermoelectric portion 101 to provide additional thermal energy transfer at a more efficient rate. Essentially, in such embodiments, the thermoelectric portion 101 is switched on if the area sought to be kept cool temporarily gets too hot. It should be noted that in such an operational mode the temperature delta across the thermoelectric device portion would necessarily increase during the course of the transient heat load. This trade off would be operatant in applications where the temperature control of the cool side is the important factor. Some embodiments can also include using the thermal diode 102 to keep the temperature gradient across the thermoelectric portion 101 at a desired delta, such as, for example: with the thermal energy sink side lower than the thermal energy source side; with the thermal energy sink side essentially the same as the thermal energy source side; the thermal energy sink side hotter than the thermal energy source side; or multiple layers of thermoelectric 101 portions and thermal diode portions 102, with a maximum delta in thermal energy across any given layer. Those skilled in the art will therefore understand that numerous embodiments are included in the present invention with many combinations and applications and many embodiments including various currents applied across layers of thermoelectric 101 and thermal diode 102 portions.

A number of embodiments of the present invention have been described. Nevertheless, it will be understood that various modifications may be made without departing from the spirit and scope of the invention. For example, various methods or equipment may be used to implement the steps described herein. In addition, various casings and packaging can also be included in order to better adapt a thermoelectric or thermodiodic device according to a specific application. Accordingly, other embodiments are within the scope of the following claims.

What is claimed is:

1. A device comprising a thermoelectric portion in thermal contact with a thermal diode portion capable of transferring thermal energy between the thermoelectric portion and the thermal diode portion in a predetermined direction.

2. The device of claim 1 wherein:
the thermoelectric portion comprises a first area and a second area; and
the thermal diode portion comprises a third area and a fourth area; and
the third area is in thermal contact with the second area; such that
a flow of thermal energy from the first area of the thermoelectric portion to the second area of the thermoelectric portion can be controlled by the application of a direct current across the thermal diode portion.

3. The device of claim 2 further comprising a second thermoelectric portion with a fifth area and a sixth area, wherein the fifth area is in thermal contact with the fourth area; and a direct current can also be applied across the second thermoelectric portion to cause thermal energy to additionally travel in the predetermined direction between the third area and the sixth area.

4. The device of claim 2 further comprising a second thermo diode portion with a fifth area and a sixth area, wherein the fifth area is in thermal contact with the first area; and a direct current can also be applied across the second thermo diode portion to cause thermal energy to additionally travel in the predetermined direction between the fifth area and the sixth area.

5. The device of claim 2 further comprising a second thermo diode portion with a fifth area and a sixth area, wherein the fifth area is in thermal contact with the forth area; and a direct current can also be applied across the second thermo diode portion to cause thermal energy to additionally travel in the predetermined direction between the fifth area and the sixth area.

6. The device of claim 1 further comprising two electrical connections in electrical contact with the thermal diode portion wherein a direct current voltage applied across the two electrical contacts can result in thermal energy being transferred between the third area and the fourth area in the predetermined direction, and limit thermal conductivity in a direction opposite to the predetermined direction at a rate greater than thermal energy is limited in the direction opposite to the predetermined direction through an thermoelectric portion equivalent to the first thermoelectric portion under equivalent conditions but without a thermal diode portion.

7. The device of claim 6 further comprising multiple alternating thermoelectric portions and thermal diode portions.

8. The device of claim 6 further comprising one or more thermoelectric portions and multiple thermal diode portions.

9. The device of claim 8 wherein at least one of the alternating portions comprises dual connections in electrical contact with one or more of the respective portions, wherein a direct current voltage applied across the connections controls a transfer of thermal energy in a predetermined direction.

10. The device of claim 8 wherein each of the thermoelectric and thermo diode portions comprise dual connections in electrical contact with the respective portions, and wherein a direct current voltage applied across a particular pair of dual connections can control a transfer of thermal energy across a respective portion with which the particular dual connections are in electrical contact.

11. The device of claim 10 wherein the thermoelectric portion comprises N-type and P-type materials arranged electrically in series and thermally in parallel.

12. The device of claim 11 wherein the N-type material comprises bismuth telluride (Bi₂Te₃) doped with selenium.

13. The device of claim 12 wherein the P-type material comprises bismuth telluride (Bi₂Te₃) doped with antimony.

14. The device of claim 11 wherein the N-type material blocks and the P-type material blocks are connected in electrically connected in series with conductive plates.

15. The device of claim 12 wherein at least one of the conductive plates comprises copper.

16. The device of claim 11 additionally comprising an electrically insulating and thermally conductive plate in thermal contact with an outer area of either a thermoelectric device portion or a thermo diode portion.

17. The device of claim 11, wherein the thermal diode portion comprises:
a conductive substrate base;
a first conductive layer comprising multiple micro sized units in electrical contact with the conductive substrate base;
a textured ionic conductor layer also in electrical contact with the units comprising the first conductive layer and covering portions of the units comprising the first conductive layer not in electrical contact with the conductive substrate base; and
an insulator layer between the units comprising the first conductive layer; and
a second conductive layer also in electrical contact with the textured ionic conductor layer.

18. The device of claim 15 wherein the device formed acts as a thermal energy pump when a direct current voltage is applied across one or more of the alternating portions.

19. The device of claim 11, wherein each thermal diode portion comprises micro sized units, essentially spherical in shape.

20. The device of claim 11, wherein each of the thermal diode portions comprise nano sized units, essentially spherical in shape.

21. The device of claim 18, wherein each of the thermal diode portions additionally comprise interstitial spaces between the essentially spherical shaped units and an insulator layer applied into said multiple interstitial spaces.

22. The device of claim 18, wherein each thermal diode portion comprises essentially silver spheres with a layer of Ag₂S.

23. The device of claim 9, wherein the thermal diode portions comprise:
a conductive substrate base;
a first conductive layer comprising multiple units in electrical contact with the conductive substrate base;
an ionic conductor layer also in electrical contact with the units comprising the first conductive layer and covering portions of the units comprising the first conductive layer not in electrical contact with the conductive substrate base;
an insulator layer between the units comprising the first conductive layer; and
a second conductive layer also in electrical contact with the ionic conductor layer.
